(19) United States
(12) Patent Application Publication
(10) Pub. No.: US 2024/0394428 A1
(43) Pub. Date: Nov. 28, 2024

(54) AREA DESIGN PROPOSAL SYSTEM AND AREA DESIGN PROPOSAL METHOD

(71) Applicants: Hitachi, Ltd., Tokyo (JP); NATIONAL UNIVERSITY CORPORATION HOKKAIDO UNIVERSITY, Sapporo-shi, Hokkaido (JP); THE SCHOOL CORPORATION KANSAI UNIVERSITY, Osaka (JP)

(72) Inventors: Mamoru OKAMOTO, Tokyo (JP); Takashi TAKEMOTO, Tokyo (JP); Hiroshi UCHIGAITO, Tokyo (JP); Thantip Sirinabhigupta KRASIENAPIBAL, Tokyo (JP); Atsuyoshi NAKAMURA, Sapporo-shi (JP); Masato KOBAYASHI, Sapporo-shi (JP); Yuta MIZUNO, Sapporo-shi (JP); Hiroshi TERAMOTO, Osaka (JP)

(21) Appl. No.: 18/692,903

(22) PCT Filed: Oct. 28, 2021
(86) PCT No.: PCT/JP2021/039808

§ 371 Date: Mar. 18, 2024

(51) Int. Cl. G06F 30/18

(52) U.S. Cl. CPC G06F 30/18

(57) ABSTRACT

It is provided an area design proposal system for proposing equipment placement and configuration of a regional energy system comprising: a long-term operation optimization module configured to output an optimum solution for the equipment placement and configuration through use of a long-term operation algorithm with input of parameters including energy equipment information, vehicle equipment information, an energy equipment introduction cost, a vehicle introduction cost, and an initial cost upper limit amount; and a short-term operation optimization module configured to calculate short-term operation evaluation results, which are evaluation results of the equipment placement and configuration, through use of a short-term operation algorithm with input of the output from the long-term operation optimization module and short-term environmental fluctuation factors, and wherein the long-term operation optimization module is configured to optimize the equipment placement and configuration with input of the short-term operation evaluation results.

### BACKGROUND OF THE INVENTION

This invention relates to an area design proposal system.

Construction of a stable, inexpensive, low-carbon, and decarbonized energy system is required in order to ensure a safe and secure living infrastructure in each region. Renewable energy such as solar power generation has great fluctuations in supply amount. In addition, in a region in which demand sites and sites suitable for renewable energy are dispersed, a large amount of cost and a long construction period are required in order to increase the capacity of a power transmission line, and coupling to a new renewable energy power system is difficult. Thus, construction of low-carbon, decarbonized, and self-sustaining energy systems that utilize a wide variety of renewable energy in neighboring regions and remote regions has been proposed. For example, there has been proposed an energy system in which small grids that integrate supply and demand mutually cooperate with each other through use of EVs and the like to adjust energy balance between the grids.

As a background technology in this technical field, the following related art has been known. That is, in WO 2020/4454 A1, there is described an energy system optimization program for causing a computer to perform processes of predetermined steps, the steps including: an input step of designating a plurality of types of energy facilities that configuring an energy system; a calculation step of acquiring at least one of an optimal system configuration and an optimal operation pattern for which a predetermined index is minimal among at least one of system configurations and operation patterns of the energy system satisfying a predetermined demand; and an output step of outputting the at least the one of the optimal system configuration and the optimal operation pattern.

In a regional energy system, it is required to determine an equipment placement and configuration proposal for a plurality of small grids and EVs and an operation policy thereon while taking into consideration uncertainties such as weather, power demand, and transport demand. In order to lower cost hurdles for introduction, profits from services other than those relating to electric power are required, but it is difficult to obtain an optimum equipment proposal involving services other than those relating to electric power through use of a related-art simulator based on a Monte Carlo method. In addition, even when power supply and demand and profits for daily services (daily short-term operation) such as transporting people and freight through use of EVs are optimized, long-term power supply and demand and profits may not be optimized in some cases, and it is required to present optimum equipment placement for small grids and an optimum operation policy thereon that optimize long-term operation involving services other than those relating to electric power while optimizing profits obtained from short-term operation.

### SUMMARY OF THE INVENTION

In view of the foregoing, this invention has an object to provide an area design proposal system that presents an equipment placement and configuration plan that optimizes long-term operation while optimizing profits obtained from short-term operation.

The representative one of inventions disclosed in this application is outlined as follows. There is provided an area design proposal system for proposing equipment placement and configuration of a regional energy system, the area design proposal system including an arithmetic device configured to execute predetermined processing, and a storage device coupled to the arithmetic device, the regional energy system is configured with a computer including the arithmetic device and the storage device, the regional energy system including a nanogrid including at least one of a power generation device or an electricity storage device, and a vehicle in which a storage battery is installed, the area design proposal system comprising: a long-term operation optimization module configured to output, by the arithmetic device, an optimum solution for the equipment placement and configuration of the regional energy system through use of a long-term operation algorithm with input of parameters including energy equipment information, vehicle equipment information, an energy equipment introduction cost, a vehicle introduction cost, and an initial cost upper limit amount; and a short-term operation optimization module configured to calculate, by the arithmetic device, short-term operation evaluation results, which are evaluation results of the equipment placement and configuration of the regional energy system, through use of a short-term operation algorithm with input of the output from the long-term operation optimization module and short-term environmental fluctuation factors, and wherein the long-term operation optimization module is configured to optimize the equipment placement and configuration of the regional energy system with input of the short-term operation evaluation results.

According to the at least one aspect of this invention, it is possible to present the equipment placement and the configuration plan that optimizes the long-term operation while optimizing the profits obtained from the short-term operation. Problems, configurations, and effects other than those described above are clarified by the following description of at least one embodiment of this invention.

### BRIEF DESCRIPTION OF THE DRAWINGS

FIG. 1 is a diagram for illustrating a regional energy system to which this invention is applied.

FIG. 2 is a diagram for illustrating an outline of equipment placement optimization for the regional energy system, which is performed by an area design proposal system according to an embodiment of this invention.

FIG. 3 is a block diagram for illustrating a logical configuration of the area design proposal system according to the embodiment.

FIG. 4 is a diagram for illustrating a physical configuration of the area design proposal system according to the embodiment.

FIG. 5 is a flow chart of area design optimization processing executed by the area design proposal system according to the embodiment.

FIG. 6 is a diagram for illustrating processing executed by the short-term calculation condition generation module.

FIG. 7 is a diagram for illustrating a flow of electric power and information in the regional energy system.

FIG. 8 is a diagram for illustrating a logical configuration of the short-term operation optimization module.

FIG. 9 is a diagram for illustrating a configuration of the batch optimization calculation module.

FIG. 10 is a flow chart of processing executed by the batch optimization calculation module.

FIG. 11 is a flow chart of processing executed by the online optimization calculation module.

FIG. 12 is a graph for showing effects of the short-term operation optimization module.

FIG. 13 is a diagram for illustrating the processing of the long-term operation optimization module.

FIG. 14 is a diagram for illustrating effects produced by the area design proposal system according to the embodiment.

### DESCRIPTION OF THE PREFERRED EMBODIMENTS

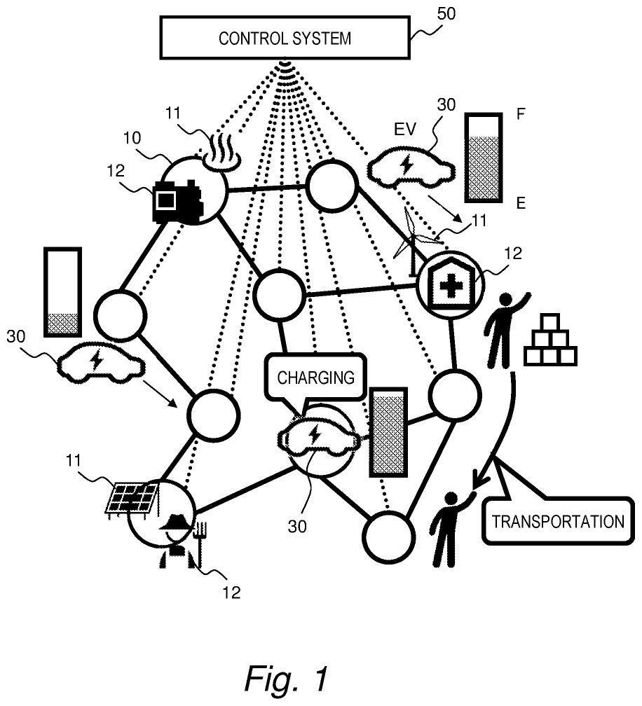

FIG. 1 is a diagram for illustrating a regional energy system to be controlled, to which this invention is applied. In FIG. 1, the solid line represents a movement route of an electric vehicle 30, and the dotted line represents a communication line for transmitting information.

A control system 50 serving as a power management system is coupled to a plurality of nanogrids 10 in a manner that allows communication therebetween.

Each of the nanogrids 10 includes a power source 11 that generates electric power, a load 12 that consumes electric power, and a power control device (not shown) that controls a power generation amount and power consumption. The nanogrid 10 may include a storage battery that accumulates electric power, in order to fill a gap between power supply and demand. The power source 11 is mainly a device that generates electric power from natural energy, such as solar power generation, wind power generation, and geothermal power generation. Examples of the load 12 include machinery equipment, a hospital and other public institutions, and agricultural machinery which consume electric power in the nanogrid 10. The electric vehicle 30 running in a relevant region also consumes electric power.

The control system 50 is coupled to the plurality of nanogrids 10 and the loads 12 in a manner that allows communication thereamong. The power control device of each of the nanogrids 10 and a power control device of each of the loads 12 each send its own power supply-demand state and a request to transport freight or people to the control system 50. The control system 50 sends an instruction to secure surplus electric power for charging of the electric vehicle 30, and sends a transportation completion report acquired from the electric vehicle 30 to the nanogrid 10. The control system 50 also outputs a calculation result to an administrator, and receives input of selection of an EV running schedule or the like from the administrator.

In a region including the nanogrids 10, the electric vehicle 30, which is a vehicle running on electricity, travels between the nanogrids 10 with use of charged electric power. The electric vehicle 30 is a delivery truck, an on-demand bus, a taxi, or the like which transports freight or people in the region. A battery for running which can be charged with electricity and discharge electricity are installed in the electric vehicle 30. The electric vehicle 30 has also installed therein a battery for power transportation which can be charged with electricity and discharge electricity, charges the battery for power transportation in one of the nanogrids 10 that has electric power to spare, and discharges battery for power transportation in one of the nanogrids 10 that is having difficulty in supplying demanded electricity, to thereby adjust power supply and demand between the nanogrids 10. The battery for power transportation and the battery for running may be one same battery or separate batteries. A battery capable of rapid charging is preferred as a battery installed in the electric vehicle 30, but a battery only capable of normal charging or a battery that can be replaced easily in a short time may be installed.

The electric vehicle 30 is preferred to be a type of electric vehicle that runs on charged electricity, but may be a vehicle that runs on energy from an internal combustion engine or a fuel battery. In this case, the nanogrids 10 provide electric power to be transported between the nanogrids 10 to the electric vehicle 30, without providing electric power for running thereto. The battery for power transportation may be omitted from the electric vehicle 30. In this case, the nanogrids 10 do not provide electric power to be transported between the nanogrids 10 to the electric vehicle 30, and power supply and demand is adjusted in places that provide electric power for running.

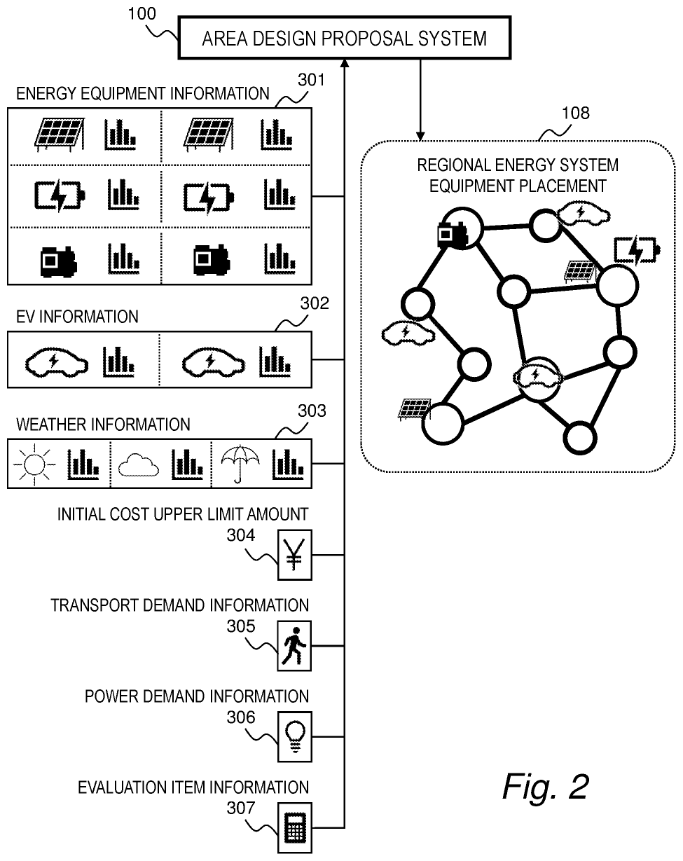

FIG. 2 is a diagram for illustrating an outline of equipment placement optimization for the regional energy system, which is performed by an area design proposal system 100 according to an embodiment of this invention.

The area design proposal system 100 calculates regional energy system equipment placement and configuration 108 based on energy equipment information 301, EV information 302, weather information 303, an initial cost upper limit amount 304, transport demand information 305, power demand information 306, and evaluation item information 307.

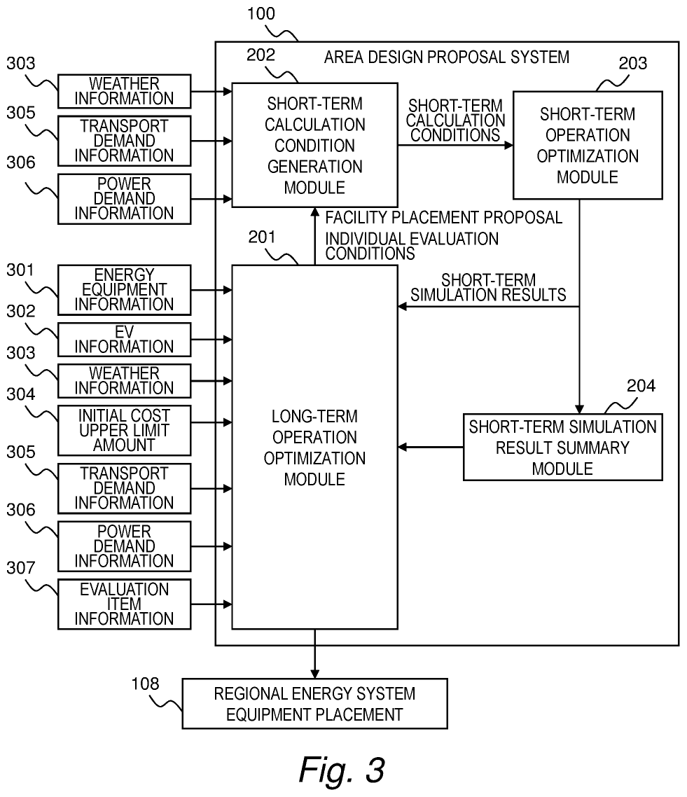

FIG. 3 is a block diagram for illustrating a logical configuration of the area design proposal system 100 according to the embodiment.

The area design proposal system 100 includes a long-term operation optimization module 201, a short-term calculation condition generation module 202, a short-term operation optimization module 203, and a short-term simulation result summary module 204.

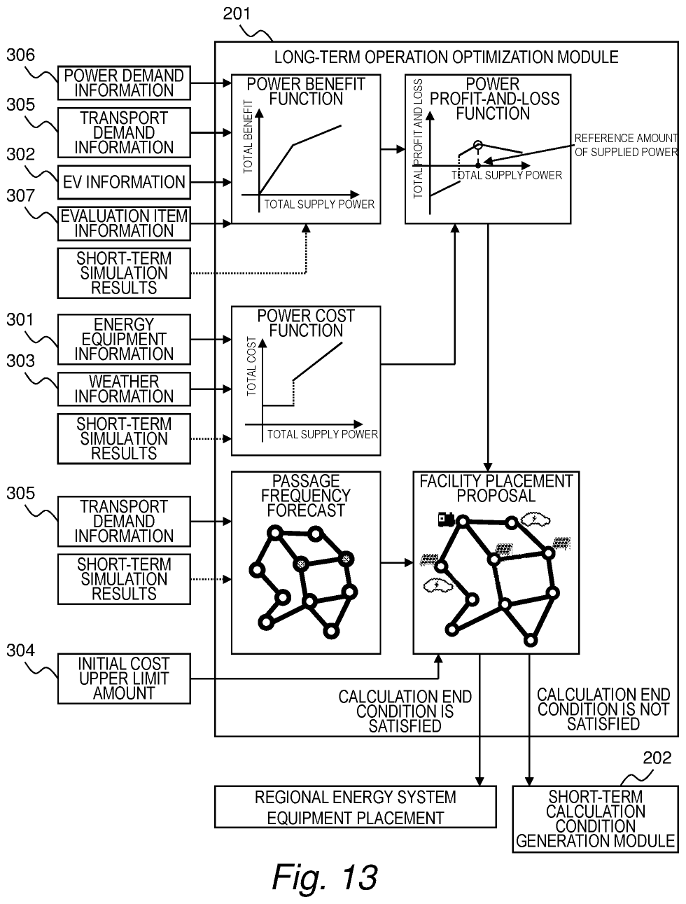

The long-term operation optimization module 201 calculates an optimum solution for equipment placement and configuration of the regional energy system (regional energy system equipment placement and configuration 108) through use of a long-term operation algorithm based on energy equipment information 301, EV information 302, weather information 303, an initial cost upper limit amount 304, transport demand information 305, power demand information 306, evaluation item information 307, and short-term simulation results, and outputs the calculated optimum solution. Details of the long-term operation optimization module 201 are described later with reference to FIG. 13.

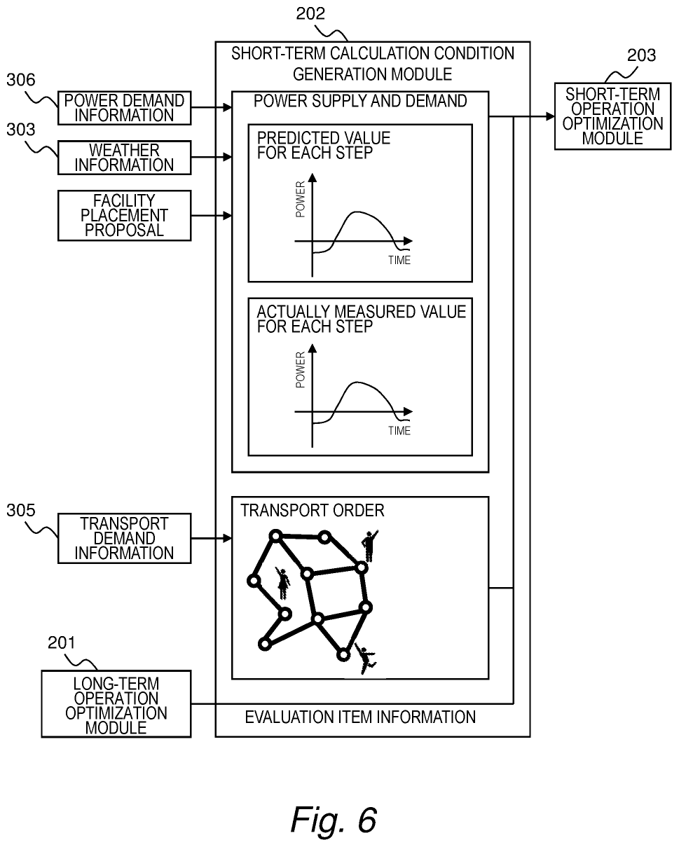

The short-term calculation condition generation module 202 generates short-term calculation conditions to be used by the short-term operation optimization module 203 based on the weather information 303, the transport demand information 305, and the power demand information 306. Details of the short-term calculation condition generation module 202 are described later with reference to FIG. 6.

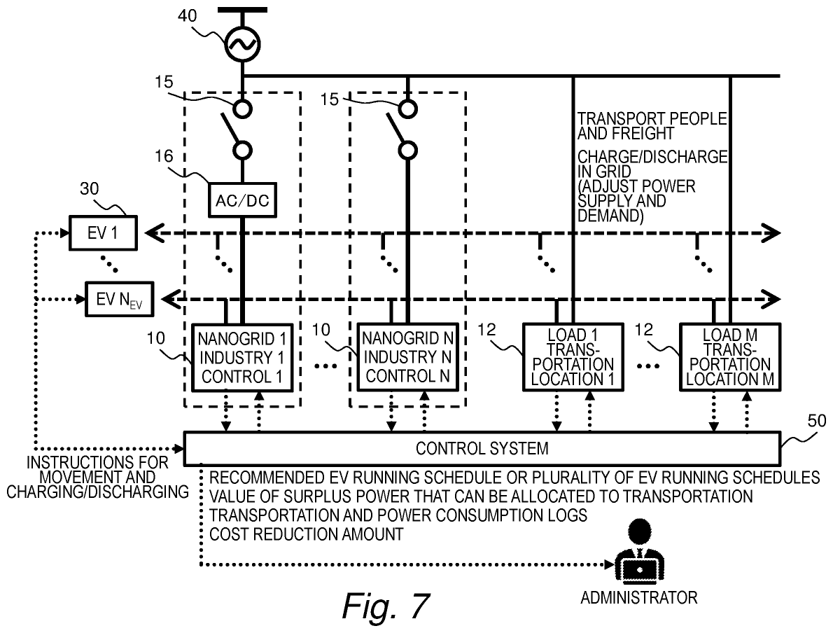

The short-term operation optimization module 203 schedules events included in the short-term calculation conditions calculated by the short-term calculation condition generation module 202, uses a facility placement proposal and individual evaluation conditions that are output from the long-term operation optimization module 201 to further perform online scheduling based on actually measured values, performs a simulation through use of a short-term operation algorithm, and output the short-term simulation results. In particular, the short-term operation optimization module 203 calculates a running schedule of the electric vehicle 30 and an operation for optimizing an amount of power generated by a power generator of the nanogrid 10, and further simulates the operation of the power generator and an operation schedule of the electric vehicle 30 so as to meet demand for power for human activities and agricultural work in the nanogrid 10. The short-term simulation results include an evaluation result of a configuration proposal relating to the equipment placement and configuration of the regional energy system. The short-term operation optimization module 203 can perform a simulation that takes into consideration environmental fluctuations and differences between predictions and actual measurements regarding power supply and demand. Details of the short-term operation optimization module 203 are described later with reference to FIG. 7 to FIG. 12. Further, the short-term operation optimization module 203 can formulate an operation of the electric vehicles 30 between the nanogrids 10 as a delivery route optimization problem (vehicle routing problem; hereinafter referred to as “VRP”), and a vehicle routing problem (VRP) solver may be used for optimization processing.

The short-term simulation result summary module 204 generates data obtained by converting short-term operation evaluation results calculated by the short-term operation optimization module 203 into a score. As this data, an output suppression amount of solar power generation or wind power generation, a storage battery consumption rate estimated from the number of times that a storage battery is charged and discharged, or a transport amount supplied by the operation of an electric vehicle may be used.

When the short-term operation optimization module 203 is operated under a plurality of conditions, simulations under those conditions may be calculated in parallel. In this case, the short-term calculation condition generation module 202 can generate a plurality of calculation conditions at a time, and the short-term operation optimization module 203 can perform stochastic evaluation by statistically processing a plurality of short-term operation evaluation results.

As described above, the short-term operation optimization module 203 simulates the operation of the nanogrid 10 and the running of the electric vehicle 30 through optimization calculation, and the long-term operation optimization module 201 has a function of improving an equipment placement and configuration plan for the regional energy system through use of the long-term operation algorithm based on results of the simulation performed by the short-term operation optimization module 203 and a summary result obtained by the short-term simulation result summary module 204.

The energy equipment information 301 is information on equipment installed in the regional energy system (for example, nanogrid 10), and includes a type and specifications of a power generation device. The EV information 302 is information on the electric vehicle 30, and includes vehicle specifications, the number of vehicles in operation, and operation policies. The weather information 303 is weather (amount of sunshine and temperature) of a relevant region. The initial cost upper limit amount 304 is an initial cost upper limit amount for additionally installing energy equipment. The transport demand information 305 includes actual records and predictions of transport orders occurring in the relevant region, and for example, when a probability of occurrence of transport is given for each time and each location, information on the transport that is expected to occur is generated. The power demand information 306 includes the demand for power to be consumed in the relevant region, a generation amount of power to be generated therein, and an amount of power to be purchased from a power system. The evaluation item information 307 includes conditions for determining the optimum solution for the equipment placement and configuration of the regional energy system.

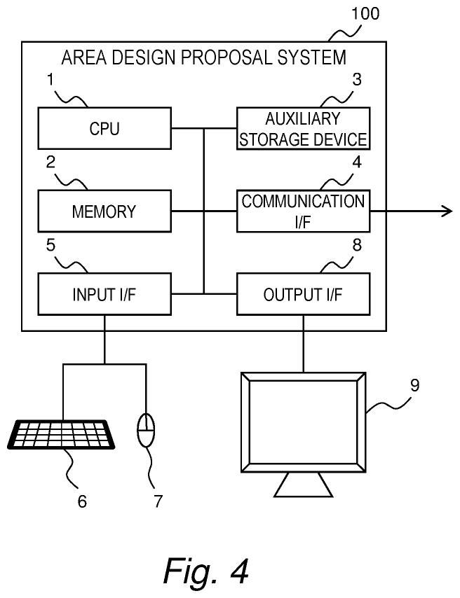

FIG. 4 is a diagram for illustrating a physical configuration of the area design proposal system 100 according to the embodiment.

The area design proposal system 100 according to the embodiment is configured from a computer including a processor (CPU) 1, a memory 2, an auxiliary storage device 3, and a communication interface 4.

The processor 1 executes a program stored in the memory 2. Part of processing executed by the processor 1 by running the program may be executed by another arithmetic device (for example, an arithmetic device built from hardware such as an FPGA or an ASIC).

The memory 2 includes a ROM, which is a non-volatile storage element, and a RAM, which is a volatile storage element. The ROM stores an unchanging program (for example, BIOS) among others. The RAM is a high-speed and volatile storage element such as a dynamic random access memory (DRAM), and temporarily stores a program executed by the processor 1 and data used in the execution of the program.

The auxiliary storage device 3 is, for example, a large-capacity and non-volatile storage device such as a magnetic storage device (an HDD) or a flash memory (an SSD), and stores a program executed by the processor 1 and data used in the execution of the program. Specifically, the program is read out of the auxiliary storage device 3, loaded onto the memory 2, and executed by the processor 1.

The communication interface 4 is a network interface device for controlling communication to and from other devices (the power control devices in the nanogrids 10 and the like) by following a predetermined protocol.

The area design proposal system 100 may include an input interface 5 and an output interface 8. The input interface 5 is an interface to which a keyboard 6, a mouse 7, and the like are coupled to receive input from an operator. The output interface 8 is an interface to which a display device 9, a printer, and the like are coupled to output a result of executing a program in a format visually recognizable to the operator. The input interface 5 and the output interface 8 may be provided by a terminal coupled to the area design proposal system 100 via a network.

A program executed by the processor 1 is provided to the area design proposal system 100 via a removable medium (a CD-ROM, a flash memory, or the like) or a network, and is stored in the non-volatile auxiliary storage device 3, which is a non-transitory storage medium. It is accordingly preferred for the area design proposal system 100 to include an interface for reading data out of a removable medium.

The area design proposal system 100 is a computer system configured on a single physical computer, or on a plurality of logically or physically configured computers, and may operate in a single thread or a plurality of threads on the same computer, or may operate on a virtual machine built on a plurality of physical computer resources. Components of the area design proposal system 100 may operate on different computers.

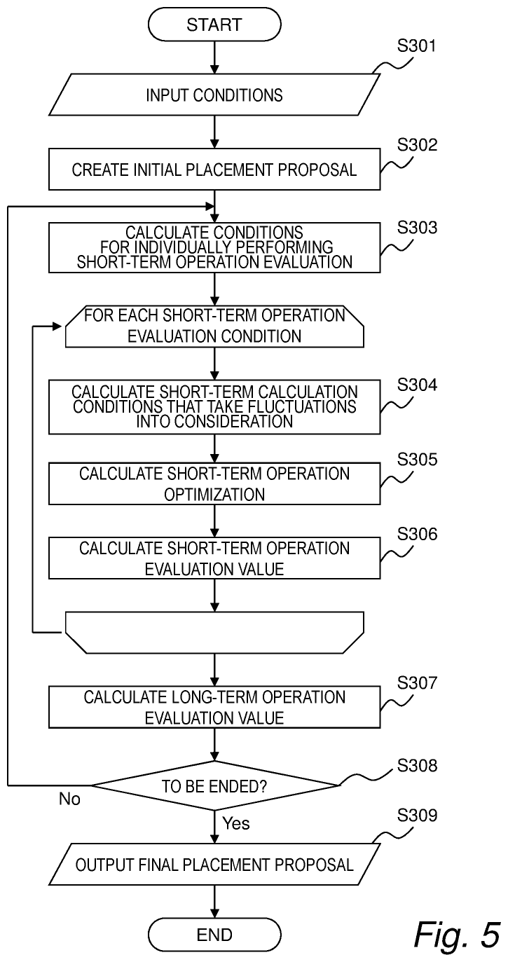

FIG. 5 is a flow chart of area design optimization processing executed by the area design proposal system 100 according to the embodiment.

First, the area design proposal system 100 receives input of simulation conditions (S301). The input simulation conditions are the energy equipment information 301, the EV information 302, the weather information 303, the initial cost upper limit amount 304, the transport demand information 305, the power demand information 306, and the evaluation item information 307.

Subsequently, the short-term calculation condition generation module 202 generates short-term calculation conditions from the weather information 303, the transport demand information 305, and the power demand information 306 among the input simulation conditions. In the area design proposal system 100 according to the embodiment, as illustrated in FIG. 3, the simulations are iteratively performed by the long-term operation optimization module 201 and the short-term operation optimization module 203, and hence the short-term calculation conditions generated by the short-term calculation condition generation module 202 are set as the initial placement proposal for the iterative simulations (S302).

Subsequently, the short-term calculation condition generation module 202 calculates conditions for individually performing short-term operation evaluation based on the created initial placement proposal or the equipment placement and configuration of the regional energy system that have been created by the long-term operation optimization module 201 (S303).

After that, the processing steps of from Step S304 to Step S306 are executed for each short-term operation evaluation condition. In a loop thereof, first, the short-term operation optimization module 203 calculates short-term calculation conditions that take fluctuations into consideration (S304). Subsequently, the short-term operation optimization module 203 performs a simulation through use of the short-term operation algorithm based on the short-term calculation conditions generated by the short-term calculation condition generation module 202 to generate short-term simulation results (S305), and calculates a short-term operation evaluation value from the generated short-term simulation results (S306).

After the evaluation values for the respective short-term operation evaluation conditions have been calculated, the long-term operation optimization module 201 calculates the equipment placement and configuration of the regional energy system through use of the long-term operation algorithm, and calculates a long-term operation evaluation value indicating evaluation of the equipment placement and configuration of the regional energy system that have been calculated (S307).

After that, the long-term operation optimization module 201 determines whether or not a calculation end condition is satisfied (S308). When the calculation end condition is not satisfied, the process returns to Step S303 to further search for the equipment placement and configuration of the regional energy system that have a higher long-term operation evaluation value. Meanwhile, when the calculation end condition is satisfied, the equipment placement and configuration of the regional energy system that have the highest long-term operation evaluation value is output (S309).

Next, processing of the short-term operation optimization module 203 in the area design proposal system 100 is described.

FIG. 6 is a diagram for illustrating processing executed by the short-term calculation condition generation module 202 that provides the simulation conditions to the short-term operation optimization module 203.

For example, when a short-term simulation is to be performed through use of discrete time steps, the short-term calculation condition generation module 202 generates simulation input parameters such as power supply-demand information at respective steps from the weather information 303 and the power demand information 306 given by the probability of occurrence in the facility placement proposal (initial placement proposal or equipment placement and configuration of the regional energy system). More specifically, the short-term calculation condition generation module 202 generates, from given information, a pair of a predicted value and an actually measured value of the power supply and demand for each step and each nanogrid.

Further, the short-term calculation condition generation module 202 determines, based on the transport demand information 305, at what step a transport order from where to where is to occur. For example, when the probability of occurrence of transport is given for each time and each location, the short-term calculation condition generation module 202 generates information (time and departure and arrival points) on transport that is expected to occur.

FIG. 7 is a diagram for illustrating a flow of electric power and information in the regional energy system. In FIG. 7, the solid line represents power transmission and distribution lines for the electric power, the dotted line represents the flow of the information, and the broken line represents transportation of electric power, freight, and people performed by the electric vehicles 30.

The nanogrid 10 balances power supply and demand within the nanogrid 10 to achieve self-sufficiency in electric power in principle, but is coupled to an electric power system 40 of the power transmission and distribution business operator so as to enable electric power to be supplied from the electric power system 40. A switch 15 is provided between the electric power system 40 and the nanogrid 10, and when the switch 15 is closed, electric power can be supplied from the electric power system 40 to the nanogrid 10. The nanogrid 10 includes a DC nanogrid that supplies DC power and an AC nanogrid that supplies AC power. The DC nanogrid is provided, between the DC nanogrid and the electric power system 40, with an inverter 16 that converts the AC power supplied from the electric power system 40 into the DC power.

As described above, the electric vehicle 30 runs between the nanogrids 10 to transport freight and people, and transports electric power from the nanogrid 10 that has electric power to spare to the nanogrid 10 that is having difficulty in supplying demanded electricity. The electric vehicle 30 is coupled to the control system 50 in a manner that allows communication therebetween, and in response to reception of instructions for movement, charging/discharging, and the like, sends reports on transportation start, transportation completion, charging start, discharging start, a stored electricity amount, and the like. Examples of the instructions for the electric vehicle 30 include the following.
stay: Instructs to stay at a present location without moving. The stored electricity amount of the electric vehicle 30 is not to be consumed, but the electric vehicle 30 is capable of functioning as a storage battery for the nanogrid 10 during that time.
pickup: Instructs to load people and freight to be transported into the electric vehicle 30. The stored electricity amount of the electric vehicle 30 is not to be consumed.
move: Instructs to proceed toward an arrival point (for example, nanogrid 10 or another destination). The stored electricity amount of the electric vehicle 30 at the next time is to have decreased by Δmove.
charge_from_grid: Instructs to charge the electric vehicle 30 by Δcharge in the nanogrid 10. A plurality of electric vehicles 30 can be simultaneously charged from the same nanogrid 10. The stored electricity amount of the electric vehicle 30 subjected to the charging is to have increased by Δcharge.
charge_to_grid: Instructs to discharge the electric vehicle 30 by Δcharge in the nanogrid 10. A plurality of electric vehicles 30 can be simultaneously discharged to the same nanogrid 10. However, the stored electricity amount of the electric vehicle 30 subjected to the discharging is to have decreased by Δcharge.

The load 12 is equipment (for example, factory or general household) that consumes electric power, and does not have the power source 11. The load 12 may be provided with the same power control device as that of the nanogrid 10.

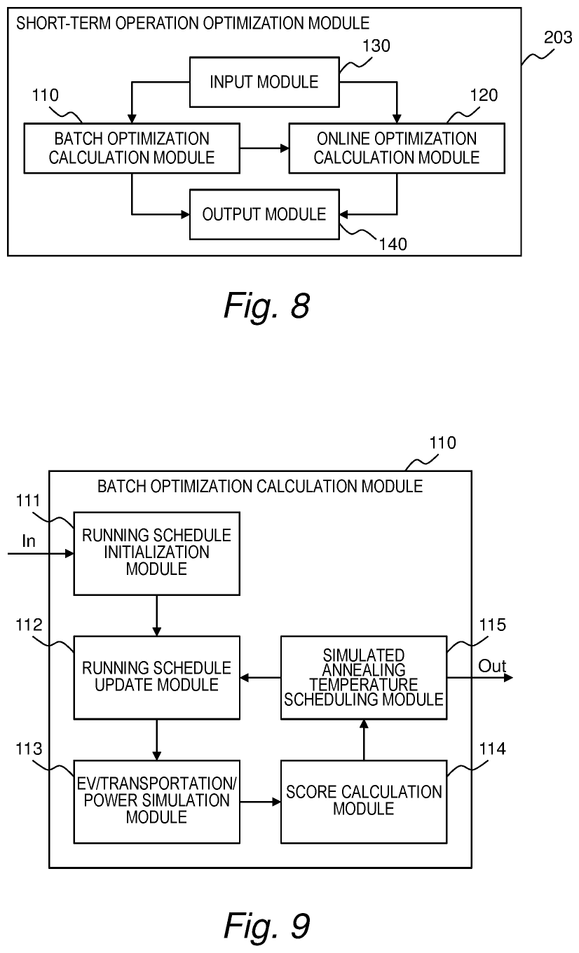

FIG. 8 is a diagram for illustrating a logical configuration of the short-term operation optimization module 203.

The short-term operation optimization module 203 includes a batch optimization calculation module 110 that performs multi-objective optimization over a relatively long period of time, an online optimization calculation module 120 that performs dynamic optimization, an input module 130 to which data to be used for processing is input, and an output module 140 that outputs results of the processing.

The batch optimization calculation module 110 is activated, for example, once a day to create a one-day provisional EV running schedule by optimizing value indices (in particular, power supply value and transportation service value), which is described later, through use of a multi-objective optimization method such as Pareto optimization based on predicted values and past data of the power generation amount, the demand for power, the transportation, and the weather. The provisional EV running schedule created by the batch optimization calculation module 110 includes provisional instructions to cause the electric vehicle 30 to load and move freight and people and to be charged/discharged in the nanogrid 10. Calculation results obtained by the batch optimization calculation module 110 are output to an administrator through the output module 140, and are output to the online optimization calculation module 120 together with a selection made by the administrator.

The online optimization calculation module 120 corrects an EV running schedule by optimizing the value indices (in particular, power supply value and transportation service value), which is described later, in a short time span (for example, every 10 minutes) through use of a multi-objective optimization method such as Pareto optimization based on actually measured values from the power control device of the nanogrid 10 and the electric vehicle 30. That is, the online optimization calculation module 120 creates a new running schedule when it is determined, at a predetermined interval (of, for example, 10 minutes), that there has occurred a discrepancy between a provisional running schedule an actual running record, there has occurred a discrepancy between the provisional running schedule and a running forecast based on a transportation request, there has occurred a discrepancy between a power supply-demand forecast and a power supply-demand actual record, or there has occurred a discrepancy between a power supply-demand forecast and a power supply-demand predicted value based on the power supply-demand actual record. The correction of the EV running schedule causes changes in a power consumption amount and a power transportation amount of the electric vehicle 30, to thereby be able to control the power supply and demand in each nanogrid 10.

The input module 130 receives input (provisional running schedule selection and selection policy) from the administrator to the area design proposal system 100, and sends the input to the batch optimization calculation module 110 or the online optimization calculation module 120. The output module 140 outputs calculation results obtained by the batch optimization calculation module 110 and the online optimization calculation module 120.

The output from the short-term operation optimization module 203 outputs the following items except that the batch optimization calculation module 110 outputs predicted values and schedules and the online optimization calculation module 120 outputs actually measured values and actual record values.

### (1) Provisional EV Running Schedule or Actual Electric Vehicle Running Record

Movement of the electric vehicle 30
   Transportation (departure point, arrival point, transportation amount, and transportation type (people or freight)) performed by the electric vehicle 30
   Charging/discharging (charging place, charging amount, discharging place, and discharging amount) of the electric vehicle 30
Number of times that transportation is performed by the electric vehicle 30
Power consumption amount of the electric vehicle 30
A plurality of provisional EV running schedules may be output as candidates for selection to be made by the administrator, or a recommended provisional EV running schedule may be output after ranking in accordance with a policy designated by the administrator.
   (2) Temporal Transition in Value of Surplus Electric Power that can be Allocated to Transportation
   (3) Amount of Charging from the Nanogrid 10 and Amount of Discharging to the Nanogrid

### (4) Value Indices Generated by Power Supply and Transportation

### (4-1) Power Supply Values

Reduction in power costs through reduction in amount of power purchased from the electric power system 40 and increase in proportion of natural energy power generation
Increase in business profits due to reduced opportunity losses through stable power supply
Stabilization of power supply through securing of the stored electricity amount of the nanogrid 10

### (4-2) Transportation Service Values

Reduction in transportation waiting time (time from occurrence of a transportation request until the transportation start) through optimization of the provisional EV running schedule and electric vehicle placement
Reduction in transportation costs through inexpensive use of surplus electric power from the nanogrid 10
Reduction in power consumption amount through optimization of running routes

### (4-3) Other Values

Reduction in environmental load through reduction in amount of carbon dioxide
Economic revitalization through improvement in store sales as a result of increased migratory due to more active movement of people

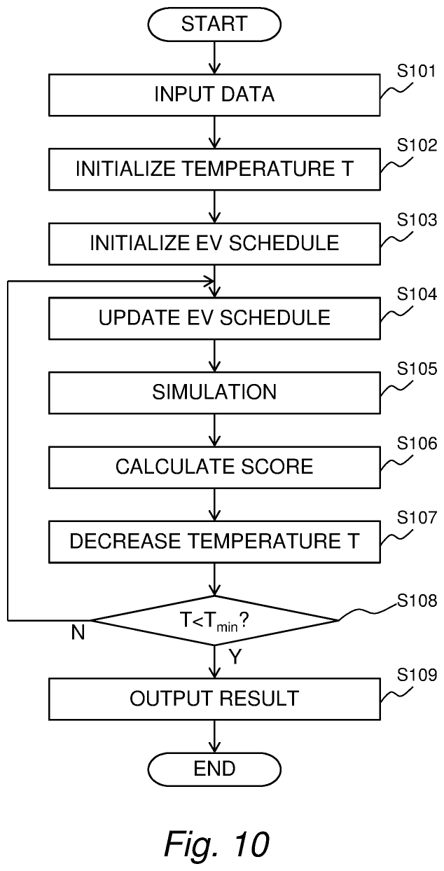

FIG. 9 is a diagram for illustrating a configuration of the batch optimization calculation module 110, and FIG. 10 is a flow chart of processing executed by the batch optimization calculation module 110.

The batch optimization calculation module 110 includes a running schedule initialization module 111, a running schedule update module 112, an EV/transportation/power simulation module 113, a score calculation module 114, and a simulated annealing temperature scheduling module 115.

The running schedule initialization module 111 creates an initial value of the EV running schedule based on a power generation schedule, a power demand forecast, and a transportation schedule that have been input. The running schedule update module 112 updates the EV running schedule through use of a simulated annealing method. The EV/transportation/power simulation module 113 executes a simulation based on the updated EV running schedule, and performs trial calculation of a log of the movement/charging/discharging of the electric vehicle 30 and a log of the power supply and demand of the nanogrid 10. The score calculation module 114 calculates various value indices based on results of the simulation. The simulated annealing temperature scheduling module 115 updates a simulated annealing temperature T used for the simulated annealing method, controls iterative calculation, and outputs a final electric vehicle running instruction.

In the batch optimization calculation module 110, as illustrated in FIG. 10, the running schedule initialization module 111 receives input of a power generation schedule, a power demand forecast, and a transportation schedule (S101). The power generation schedule and the power demand forecast are input from the power control device of the nanogrid 10. The transportation schedule includes data such as the transportation type (people or freight), occurrence places (departure point and arrival point), and the probability of occurrence, and can be acquired from a shipper that ships freight, a delivery business operator that transports freight by the electric vehicle 30, or a vehicle running business operator that transports people by the electric vehicle 30 (EV bus or EV taxi). The running schedule initialization module 111 may receive input of a policy, such as a target value of balance between electric power and transportation, for the nanogrid 10 as the requirement arises.

After that, the running schedule initialization module 111 initializes the temperature T used for the simulated annealing method to a high temperature (S102), and creates an initial value of the EV running schedule (S103).

Subsequently, the running schedule update module 112 updates the EV running schedule by causing the EV running schedule (initial value) created by the running schedule initialization module 111 to transition to a vicinity in the simulated annealing method (S104). The vicinity refers to a close solution, for example, a running schedule obtained by slightly changing the operation of the electric vehicle 30.

Subsequently, the EV/transportation/power simulation module 113 operates the electric vehicle 30 in the simulator based on the EV running schedule updated by the running schedule update module 112, and simulates the real world in terms of the operation of the nanogrid 10, the transportation by the electric vehicle 30, and the like (S105).

Subsequently, the score calculation module 114 calculates the electric power, transportation values, and costs from a transportation log and a charging/discharging log of the electric vehicle 30 and a power supply-demand log (such as changes in the stored electricity amount) of the nanogrid 10, which are the results of the simulation performed by the EV/transportation/power simulation module 113.

The simulated annealing temperature scheduling module 115 decreases the simulated annealing temperature T (S107) and determines whether or not the simulated annealing temperature Tis smaller than a minimum temperature Tₘᵢₙ (S108). When the simulated annealing temperature T is equal to or higher than the minimum temperature Tₘᵢₙ, the process returns to Step S104 to continue the processing at the updated simulated annealing temperature T. Meanwhile, when the simulated annealing temperature T is smaller than the minimum temperature Tₘᵢₙ, the iterative calculation is ended, and the result is output to a user (S109). Further, the calculation results obtained by the batch optimization calculation module 110 are input to the online optimization calculation module 120 together with a selection made by the user.

An example in which the simulated annealing method is used for the batch optimization calculation module 110 has been described, but another method for obtaining the optimum solution may be used.

The batch optimization calculation module 110 may rank a plurality of provisional running schedules in accordance with a policy input by the administrator. Further, the output module 140 may output the provisional running schedule in accordance with the ranking.

Next, the online optimization calculation module 120 is described. The online optimization calculation module 120 can use the simulated annealing method, and can be configured in the same manner as the batch optimization calculation module 110 using the simulated annealing method, which has been described with reference to FIG. 9. Thus, description of the configuration is omitted.

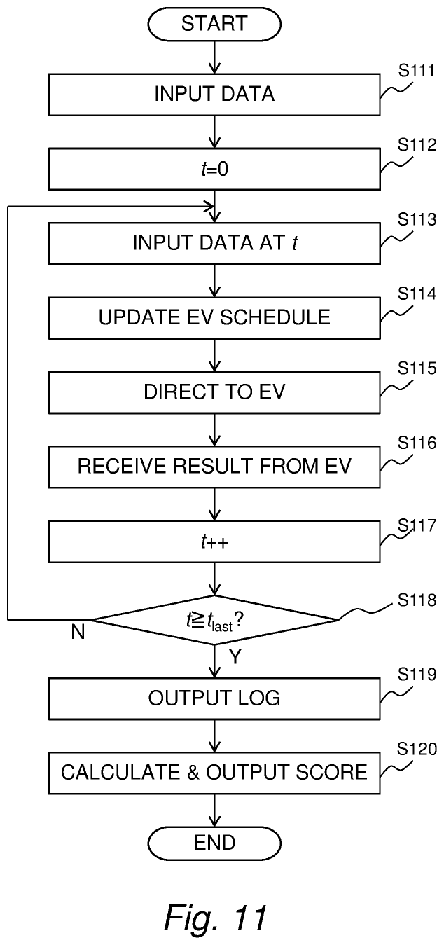

FIG. 11 is a flow chart of processing executed by the online optimization calculation module 120.

First, the online optimization calculation module 120 receives input of the selection of the provisional EV running schedule made by the administrator together with the calculation results (such as a provisional EV running schedule, a predicted value of the temporal transition in value of the surplus electric power, a predicted value of the amount of discharging to the nanogrid 10, a predicted value of each value) obtained by the batch optimization calculation module 110 (S111).

Subsequently, the online optimization calculation module 120 initializes a time t to zero (S112), and receives input of data at the time t (S113). The data input to the online optimization calculation module 120 includes the actual record of the transportation, actually measured value of the power generation amount, and actually measured value of power consumption at the time t, and the transportation schedule and corrected values of the predictions of the power generation amount and the power consumption after the time t.

Subsequently, the online optimization calculation module 120 updates the EV running schedule (on transportation and charging/discharging) based on the input data at the time t (S114).

Subsequently, the online optimization calculation module 120 directs the electric vehicle 30 to use the updated EV running schedule (S115).

Subsequently, the online optimization calculation module 120 receives, from the electric vehicle 30, transportation results (such as the departure point, the arrival point, the transportation amount, the transportation type (people or freight), the charging/discharging place, and the charging/discharging amount that are included in the transportation log) and a state log (including the position and the stored electricity amount) (S116).

Subsequently, the online optimization calculation module 120 increments the time t by one step for advancement to the next time (S117), and determines whether or not the time t is equal to or larger than a final time tₗₐₛₜ (S118). When the time t is smaller than the final time tₗₐₛₜ, the process returns to Step S113 to continue the calculation.

Meanwhile, when the time t is equal to or larger than the final time tₗₐₛₜ, calculation results (a log) are output (S119). The output log includes the transportation results (a transportation log including the departure point, the arrival point, the transportation amount, the transportation type (people or freight), the charging/discharging place, and the charging/discharging amount) and the state log (position and charging amount). Not only final results but also a log at the time t may be output.

Subsequently, the online optimization calculation module 120 calculates various value indices from the final results based on the actual records of the transportation and the actually measured values, and outputs the calculation results of the value indices (S120).

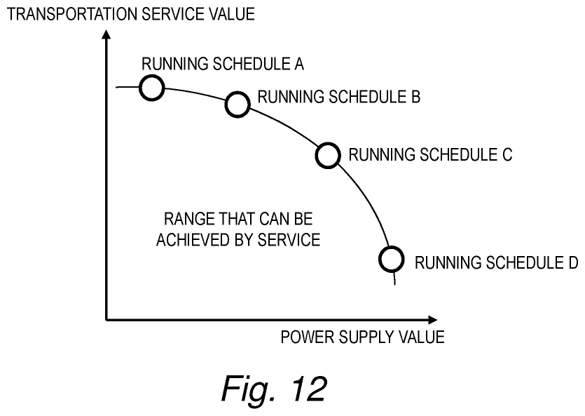

FIG. 12 is a graph for showing effects of the short-term operation optimization module 203.

As shown in FIG. 12, in the EV running schedule created by the short-term operation optimization module 203, the power supply value decreases as the transportation service value increases, and the transportation service value decreases as the power supply value increases. This is because, for example, energy consumption increases when the transportation service value is improved by increasing the number of times of running to reduce a waiting time or increasing a transportation speed.

As described with reference to FIG. 10, the batch optimization calculation module 110 creates and outputs a plurality of EV running schedules in which the power supply value and the transportation service value are optimized. For example, such a graph indicating degrees of values as shown in FIG. 12 may be displayed on a screen to prompt the administrator to make a selection from the plurality of EV running schedules. This screen may display details of the selected EV running schedule when a display location of the EV running schedule is selected.

In addition, when an unexpected event such as a sudden change in weather occurs and the power generation amount decreases, the scheduled running of the electric vehicles 30 and operation of the device are halted, thereby lowering the power supply value and the transport service value. However, the online optimization calculation module 120 optimizes the running schedule in accordance with the current situation, to thereby be able to suppress a degree of decrease in the power supply value and the transport service value.

The EV running schedule created by the control system 50 described above can be, for example, provided to farmers to move crops. In other words, when regular services of electric trucks are run in order for farmers to ship crops and transport crops to processing plants, the power generation amount and electric power consumed by agricultural work change depending on the weather. For that reason, depending on a cause of the change, a frequency of the regular services is adjusted, and the number of electric vehicles 30 (EV trucks) to be allocated to the nanogrid 10 for electricity storage purposes is optimized. Thus, it is possible to achieve improvement in values of a local society through multi-objective optimization of energy and transportation services in, for example, a region having a weak transportation network.

Next, processing of the long-term operation optimization module 201 is described. FIG. 13 is a diagram for illustrating the processing of the long-term operation optimization module 201.

The long-term operation optimization module 201 calculates a power benefit function based on the EV information 302, the transport demand information 305, the power demand information 306, the evaluation item information 307, and the short-term simulation results. The power benefit function is a function that represents a relationship of a total benefit with respect to a total amount of power supplied per unit period. The benefit may be directly expressed in monetary terms, or may be expressed in terms of a scale adjusted in consideration of social and environmental effectiveness. The user can control a relationship between the amount of supplied power and the benefit in the power benefit function through use of the evaluation conditions set in the evaluation item information 307.

The power benefit function can be calculated by, for example, the following method.
1) A total demand for power per unit period is calculated from the power demand information 306.
2) Up to the calculated total demand for power, the benefit from the power supply is expressed as a linear function with a power price being used as a proportional coefficient (slope). As the power price, a price determined by the wholesale power market or a specific retail electricity supplier may be referred to, or a unique price may be set in the system.
3) An average value of a transportation distance per transport order is calculated from the transport demand information 305, and is multiplied by an average value of a power consumption rate of the EV information 302 to calculate an average power consumption amount per transport order. In addition, the required number of electric vehicles 30 is calculated based on an average speed, number of transport orders, and average transport distance of a given electric vehicle 30.
4) The expected number of transport orders within a unit period is multiplied by the power consumption amount calculated in the item 3) to calculate the total demand for power required for the transport per unit period.
5) Up to the total demand for power required for the transport, which has been calculated in the item 4), beyond the total demand for power, which has been calculated in the item 1), the benefit from the power supply is expressed as a linear function with the power price being used as a proportional coefficient (slope). The proportional coefficient may be the same as the coefficient determined in the item 2), or may be determined separately.

Instead of using the power benefit function, a list of pairs of the amount of power and the benefit may be created, and allocation may be performed in descending order of the benefit per amount of power.

The long-term operation optimization module 201 also calculates a power cost function based on the energy equipment information 301, the weather information 303, and the short-term simulation results. The power cost function is a function representing a total cost with respect to the total amount of power supplied per unit period. The benefit may be directly described in monetary terms, or may be described in terms of a scale adjusted in consideration of social and environmental effectiveness. The user can control a relationship between the amount of supplied power and the cost in the power cost function through use of the evaluation conditions set in the evaluation item information 307.

The power cost function can be calculated by, for example, the following method.
1) A total power generation amount per unit period is calculated from an amount of solar radiation and wind power of the weather information 303.
2) A cost with respect to the amount of power that can be supplied is calculated with reference to information on each product of the energy equipment information 301.
3) A power cost function is created by integrating the cost with respect to the amount of power that can be supplied, which has been calculated in the item 2), in ascending order of the cost per amount of power.

The long-term operation optimization module 201 also creates a power profit-and-loss function by subtracting the power cost function from the power benefit function, and sets the amount of supplied power exhibiting the maximum value of the power profit-and-loss function as a reference amount of supplied power. When the power cost function is created through use of the above-mentioned method, details of energy equipment to be placed in the system can be calculated through introduction in ascending order of the cost per amount of power.

In order to calculate the configuration in which equipment for supplying the above-mentioned reference amount of supplied power is placed in the regional energy system, a passage frequency forecast is created through use of the transport demand information 305. Specifically, occurrence frequencies on each transport route estimated from the predicted values of the transport demand information 305 are added at nodes on the shortest route to obtain passage frequency predicted values.

The long-term operation optimization module 201 also calculates a facility placement proposal from the power profit-and-loss function and the passage frequency predicted values. Costs (such as expenses and areas) required for additionally installing new equipment may be calculated together with the equipment placement and configuration of the regional energy system.

The facility placement proposal can be calculated by, for example, the following method.
1) Equipment for covering the demand for power in a power demand area described in the power demand information 306 is placed within ranges of the reference amount of supplied power and the initial cost upper limit amount 304. Excess and deficiency of the demand for power are calculated based on an integrated value during the unit period.
2) When the reference amount of supplied power cannot be covered even with the equipment having been placed in the power demand area, equipment corresponding to an insufficient supply capacity is placed at a node exhibiting a high passage frequency predicted value within the range of the initial cost upper limit amount 304.
3) The electric vehicles 30 the number of which corresponds to an amount that covers the transport demand estimated from the transport demand information 305 are placed within the range of the initial cost upper limit amount 304.

Further, the long-term operation optimization module 201 determines whether or not the calculation end condition is satisfied. When the calculation end condition is satisfied, the calculated facility placement proposal is output as the regional energy system equipment placement and configuration. Meanwhile, when the calculation end condition is not satisfied, the calculated facility placement proposal is output to the short-term calculation condition generation module 202, and the short-term simulation is performed.

For example, the calculation end condition may be set based on a calculation resource. For example, it may be determined that the calculation is to be ended when a CPU time used for the simulation or the number of simulations reaches an upper limit. Further, as the calculation end condition, for example, a condition that an evaluation value of the facility placement proposal has reached a target value set in advance or a condition that the evaluation value has converged may be used.

Then, from the obtained short-term simulation results, the power benefit function, the power cost function, and the passage frequency forecast are updated, and a facility placement proposal is further created. For example, the transport demand included in the short-term simulation results is used to update the power benefit function, an equipment usage rate included in the short-term simulation results is used to update the power cost function, and the number of passages in a vehicle movement log included in the short-term simulation results is used to update the passage frequency predicted value.

The power benefit function, the power cost function, and the passage frequency predicted value may be updated by inheriting previous predicted values as in the following equation.

(new predicted value)=((predicted value of current short-term simulation result)+(previous predicted value))+2

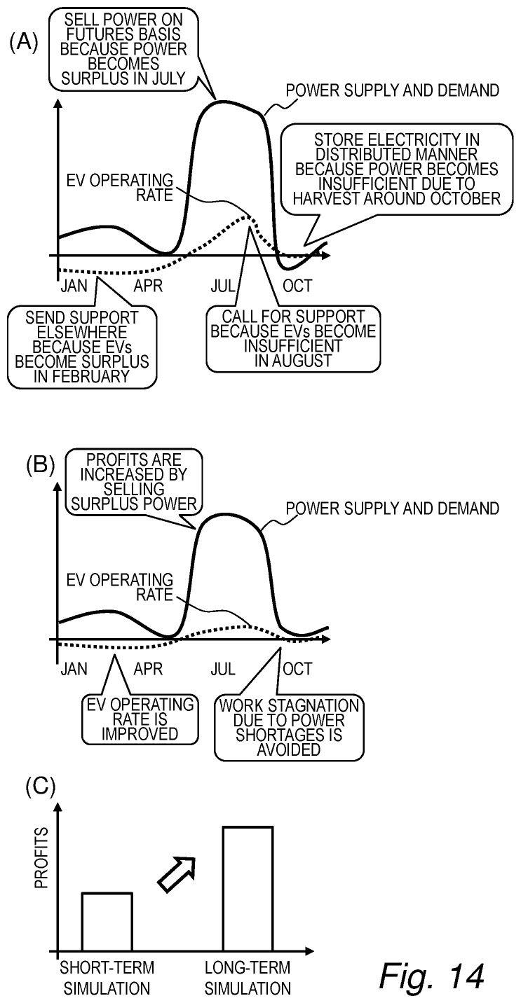

FIG. 14 is a diagram for illustrating effects produced by the area design proposal system 100 according to the embodiment.

FIG. 14 (A) shows the power supply and demand and an operating rate of the electric vehicles 30 that have been optimized by a short-term simulation before the area design proposal system 100 is applied. The optimization based on the short-term simulation does not take long-term optimization into consideration, and hence, in terms of the demand for power, it is expected that the electric power is to become surplus in July, thereby requiring the electric power to be sold on a futures basis. It is also expected that the electric power used for harvesting is to become insufficient around October, and hence electricity storage is required in a distributed manner. In terms of the operation of the electric vehicles 30, it is also expected that the operating rate of the electric vehicles 30 is to decrease in February, and hence it is possible to send support elsewhere. In addition, the operating rate of the electric vehicles 30 is expected to rise in August, and hence it is required to call for support from elsewhere.

FIG. 14 (B) shows the power supply and demand and an operating rate of the electric vehicles 30 that have been optimized by a long-term simulation after the area design proposal system 100 is applied. Through optimization based on the long-term simulation, it is possible to increase profits by selling electric power that becomes surplus in July in terms of the demand for power. In addition, it is possible to avoid work stagnation due to power shortages in October. Further, it is possible to improve the operating rate of the electric vehicles 30 in February.

FIG. 14 (C) shows a difference in profits between a case of using only the short-term simulation and a case in which the long-term simulation is applied. In the case of using only the short-term simulation, profits from only the operation of the electric vehicles 30 and a power generation facility are small, and opportunities to make profits are missed. However, when the long-term simulation is performed, it is possible to optimize the regional energy system equipment placement and configuration and to reduce discarded surplus power and the number of infrequently operated electric vehicles 30, thereby being able to improve profits.

As described above, with the area design proposal system 100 according to the embodiment of this invention, optimization can be performed in accordance with short-term operation evaluation corresponding to the equipment placement and configuration of the regional energy system, and a detailed system including the environmental fluctuations can be optimized. Further, users can evaluate in advance impacts that are difficult to predict during the planning and changing stages for the equipment placement and configuration, thereby being able to reduce business risks.

This invention is not limited to the above-described embodiments but includes various modifications. The above-described embodiments are explained in details for better understanding of this invention and are not limited to those including all the configurations described above. A part of the configuration of one embodiment may be replaced with that of another embodiment; the configuration of one embodiment may be incorporated to the configuration of another embodiment. A part of the configuration of each embodiment may be added, deleted, or replaced by that of a different configuration.

The above-described configurations, functions, processing modules, and processing means, for all or a part of them, may be implemented by hardware: for example, by designing an integrated circuit, and may be implemented by software, which means that a processor interprets and executes programs providing the functions.

The information of programs, tables, and files to implement the functions may be stored in a storage device such as a memory, a hard disk drive, or an SSD (a Solid State Drive), or a storage medium such as an IC card, or an SD card.

The drawings illustrate control lines and information lines as considered necessary for explanation but do not illustrate all control lines or information lines in the products. It can be considered that almost of all components are actually interconnected.

What is claimed is:

1. An area design proposal system for proposing equipment placement and configuration of a regional energy system, the area design proposal system including an arithmetic device configured to execute predetermined processing; and a storage device coupled to the arithmetic device,
the regional energy system is configured with a computer including the arithmetic device and the storage device,
the regional energy system including a nanogrid including at least one of a power generation device or an electricity storage device, and a vehicle in which a storage battery is installed,
the area design proposal system comprising:
a long-term operation optimization module configured to output, by the arithmetic device, an optimum solution for the equipment placement and configuration of the regional energy system through use of a long-term operation algorithm with input of parameters including energy equipment information, vehicle equipment information, an energy equipment introduction cost, a vehicle introduction cost, and an initial cost upper limit amount; and
a short-term operation optimization module configured to calculate, by the arithmetic device, short-term operation evaluation results, which are evaluation results of the equipment placement and configuration of the regional energy system, through use of a short-term operation algorithm with input of the output from the long-term operation optimization module and short-term environmental fluctuation factors, and
wherein the long-term operation optimization module is configured to optimize the equipment placement and configuration of the regional energy system with input of the short-term operation evaluation results.

2. The area design proposal system according to claim 1,
wherein the short-term operation optimization module is configured to calculate the short-term operation evaluation results with the environmental fluctuation factors being set to: weather information derived from fluctuations in natural environment; and transport demand information and power demand information that are derived from human activities, and
wherein the weather information, the transport demand information, and the power demand information are each represented by a probability of an event.

3. The area design proposal system according to claim 1, further comprising a short-term simulation result summary module configured to generate, by the arithmetic device, data having a granularity required for the long-term operation optimization module by thinning out the short-term operation evaluation results in terms of time.

4. The area design proposal system according to claim 1, wherein the short-term operation optimization module is configured to calculate a vehicle running schedule so as to optimize the vehicle running schedule, and schedule a power generation amount and vehicle running so as to satisfy demand for power for agricultural work.

5. The area design proposal system according to claim 1, wherein the short-term operation optimization module is configured to process operation of vehicles between nanogrids as a delivery route optimization problem.

6. The area design proposal system according to claim 1,
wherein the energy equipment information includes a type and specifications of the power generation device, and
wherein the vehicle equipment information includes vehicle specifications.

7. The area design proposal system according to claim 1, wherein the long-term operation optimization module is configured to output a required cost together with the equipment placement and configuration of the regional energy system.

8. The area design proposal system according to claim 1, wherein the short-term operation optimization module is configured to execute arithmetic processing under a plurality of conditions in parallel.

9. An area design proposal method of proposing, by an area design proposal system, equipment placement and configuration of a regional energy system, the area design proposal system including a computer including an arithmetic device configured to execute predetermined processing, and a storage device coupled to the arithmetic device,
the regional energy system including a nanogrid including at least one of a power generation device or an electricity storage device, and a vehicle in which a storage battery is installed,
the area design proposal method comprising:
a long-term operation optimization step of outputting, by the arithmetic device, an optimum solution for the equipment placement and configuration of the regional energy system through use of a long-term operation algorithm with input of parameters including energy equipment information, vehicle equipment information, an energy equipment introduction cost, a vehicle introduction cost, and an initial cost upper limit amount; and
a short-term operation optimization step of calculating, by the arithmetic device, short-term operation evaluation results, which are evaluation results of the equipment placement and configuration of the regional energy system, through use of a short-term operation algorithm with input of the output obtained in the long-term operation optimization step and short-term environmental fluctuation factors, and
wherein the long-term operation optimization step includes optimizing, by the arithmetic device, the equipment placement and configuration of the regional energy system with input of the short-term operation evaluation results.
